(19) United States
(12) Patent Application Publication
(10) Pub. No.: US 2024/0145260 A1
(43) Pub. Date: May 2, 2024

(54) AIRFLOW HEATING MODULE FOR EQUIPMENT FRONT-END MODULE

(71) Applicant: Kogaku Technology Inc., Miaoli County (TW)

(72) Inventors: Yueh-Lin CHIANG, Miaoli County (TW); Hsin-Jan PAI, Miaoli County (TW); Ying-Feng LEE, Miaoli County (TW); Ling-Chiao HUANG, Miaoli County (TW)

(21) Appl. No.: 18/089,436

(22) Filed: Dec. 27, 2022

(30) Foreign Application Priority Data
Nov. 1, 2022 (TW) 111211937

(51) Int. Cl. H01L 21/67

(52) U.S. Cl. CPC H01L 21/67017

(57) ABSTRACT

An airflow heating module for an equipment front-end module, including: a first perforated plate including a first plurality of holes used as airflow inlets; a second perforated plate including a second plurality of holes used as airflow outlets; a plurality of heaters provided between the first and the second perforated plates; and an active air intake device provided on the first perforated plate to accelerate airflow flowing through the first plurality of holes and past the plurality of heaters, such that the airflow carries heat generated by the heaters and passes through the second plurality of holes. Each of the heaters includes a heating tube and a fin. The fin is formed helically around the heating tube and attached thereto.

### CROSS REFERENCE TO RELATED APPLICATIONS

The present application claims priority from Taiwan Patent application No. TW 111211937 filed on Nov. 1, 2022, entitled “AIRFLOW HEATING MODULE FOR EQUIPMENT FRONT-END MODULE”, the content of which is hereby incorporated by reference in their entirety for all purposes.

### TECHNICAL FIELD

The present invention relates to an airflow heating module, and particularly to an airflow heating module for equipment front-end modules.

### BACKGROUND

Semiconductor processing apparatuses can typically be used to perform processes, such as deposition, etching, patterning, cleaning, ashing, etc., to semiconductor wafers. Generally, a semiconductor processing apparatus may include equipment front end modules (EFEMs). One major function of the EFEMs is providing a clean environment to prevent semiconductor wafers from being contaminated by ambient environment during the transfer of the semiconductors to processing chambers. In addition, in order to stabilize the temperature of a semiconductor processing environment for improving the efficiency of semiconductor processing, airflow entering the EFEMs may typically be heated and maintained at a specific temperature which facilitates subsequent processes. Accordingly, temperature control for EFEMs is important.

However, the structure of a heating module for heating the airflow entering the EFEMs may cause an increase of airflow resistance, which in turn causes insufficient air volume entering the EFEMs and a decreased efficiency of heat transfer. Additionally, when the EFEMs are temporarily shut down for some reason, the residual heat inside the EFEMs cannot dissipate timely, which often causes damages to internal components of the EFEMs due to overheating.

Therefore, an airflow heating module for EFEMs is required for increasing air volume entering the EFEMs to elevate heat transfer efficiency, and removing residual heat when the EFEMs are shut down to prevent internal components from being damaged by overheating.

### SUMMARY OF THE INVENTION

In order to solve the problems mentioned above, according to an embodiment of the present invention, an airflow heating module for equipment front-end module is provided. The airflow heating module comprises: a first perforated plate which includes a first plurality of holes used as airflow inlets; a second perforated plate which includes a second plurality of holes used as airflow outlets; a plurality of heaters provided between the first perforated plate and the second perforated plate; and an active air intake device provided on the first perforated plate, and configured to accelerate airflow flowing through the first plurality of holes and flowing past the plurality of heaters, such that the airflow carries heat generated by the plurality of heaters and passes through the second plurality of holes. Each of the plurality of heaters includes a heating tube and a fin. The fin is formed helically around the heating tube and is attached to the heating tube.

The airflow heating module of the present invention can increase air volume entering the EFEMs to elevate heat transfer efficiency, and remove residual heat when the EFEMs are shut down to prevent internal components from being damaged by overheating. In addition, by spatially arranging an air intake module (the active air intake device) and the heating module, the uniformity of airflow heating can be improved.

Other embodiments and advantages of the present invention will become more obvious from the following Detailed Description with reference to the accompanying drawings. In addition, well-known components and principles which will not be described in detail in order not to unnecessarily obscure the present invention.

### BRIEF DESCRIPTION OF THE DRAWINGS

In the drawings of the present invention, like reference numerals are used to indicate same and/or similar components. Additionally, the drawings are for illustrative purposes only and therefore not drawn to scale.

FIG. 1 illustrates a perspective view of an airflow heating module for equipment front end modules (EFEMs) according to an embodiment of the present invention.

FIG. 2 is a rear view of the airflow heating module as shown in FIG. 1.

FIG. 3 is a partial exploded view of the airflow heating module as shown in FIG. 1.

FIG. 4 is a cross-sectional schematic view taken along a line A′-A′ shown in FIG. 1.

FIG. 5 is a perspective view illustrating the airflow heating module shown in FIG. 1 viewed from another perspective, with a housing of the airflow heating module removed.

FIG. 6A illustrates a perspective view of a heater; FIG. 6B is a side view of the heater shown in FIG. 6A; and FIG. 6C is a partial enlarged view of a part A in FIG. 6B, according to an embodiment of the present invention.

FIG. 7A illustrates a perspective view of heaters as shown in FIG. 6A arranged in multiple rows; and FIG. 7B is a front view of the multiple rows of heaters shown in FIG. 7A, according to an embodiment of the present invention.

FIG. 8 illustrates a schematic view of a heater according to another embodiment of the present invention.

FIG. 9A illustrates a perspective view of heaters as shown in FIG. 8 arranged in multiple rows; and FIG. 9B is a front view of the multiple rows of heaters shown in FIG. 9A, according to an embodiment of the present invention.

FIG. 10 illustrates a perspective view showing an EFEM equipped with an airflow heating module, according to an embodiment of the present invention.

### DETAILED DESCRIPTION

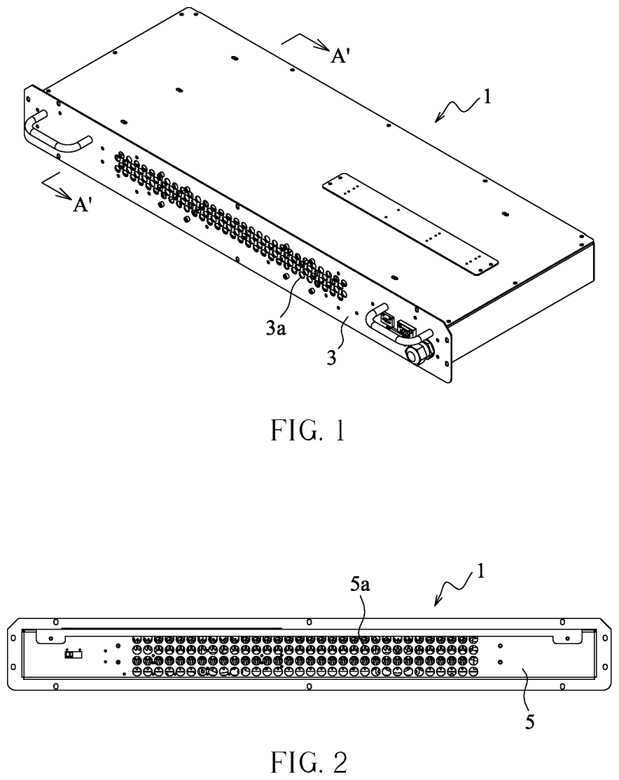

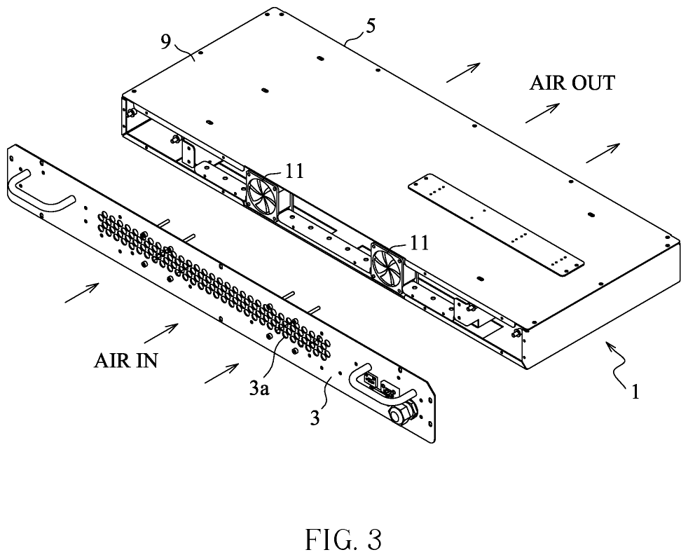

FIG. 1 illustrates a perspective view of an airflow heating module 1 for equipment front end modules (EFEMs) according to an embodiment of the present invention. FIG. 2 is a rear view of the airflow heating module 1 as shown in FIG. 1. FIG. 3 is a partial exploded view of the airflow heating module 1 as shown in FIG. 1. As shown in FIGS. 1-3, the airflow heating module 1 may comprise a first perforated plate 3 and a second perforated plate 5. The first perforated plate 3 may comprise a first plurality of holes 3a configured to act as airflow inlets, and the second perforated plate 5 may comprise a second plurality of holes 5a configured to act as airflow outlets.

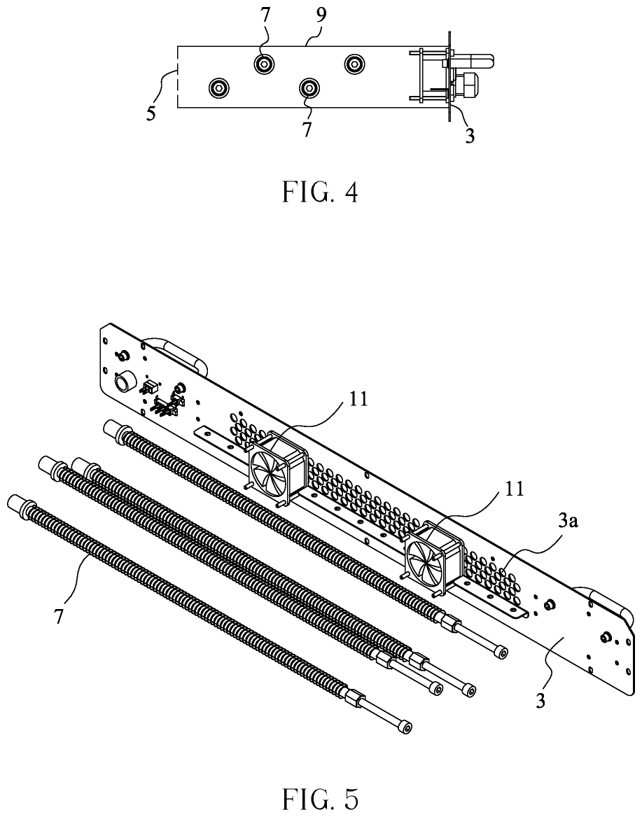

FIG. 4 is a cross-sectional schematic view taken along a line A′-A′ shown in FIG. 1. As shown in FIG. 4, the airflow heating module 1 may comprise a plurality of heaters 7. The plurality of heaters 7 are provided between the first perforated plate 3 and the second perforated plate 5. As shown, the airflow heating module may further comprise a housing 9. The housing 9 may be configured to enclose the plurality of heaters 7 to improve the heating efficiency of the heaters 7.

FIG. 5 is a perspective view illustrating the airflow heating module 1 shown in FIG. 1 viewed from another perspective, with the housing 9 removed. As shown in FIG. 3 and FIG. 5, the airflow heating module 1 may comprise an active air intake device 11. The active air intake device 11 is disposed on the first perforated plate 3, and is configured to accelerate the airflow flowing through the first plurality of holes 3a of the first perforated plate 3 and flowing past the plurality of heaters 7, such that the airflow carries the heat generated by the plurality of heaters 7 through the second plurality of holes 5a of the second perforated plate 5. In an embodiment of the present invention, the active air intake device 11 may be an air intake fan, for example, but it is not limited thereto. While two active air intake devices 11 are shown in FIGS. 3 and 5, those having ordinary skill in the art may increase or decrease the number of the active air intake device 11 based on actual requirement.

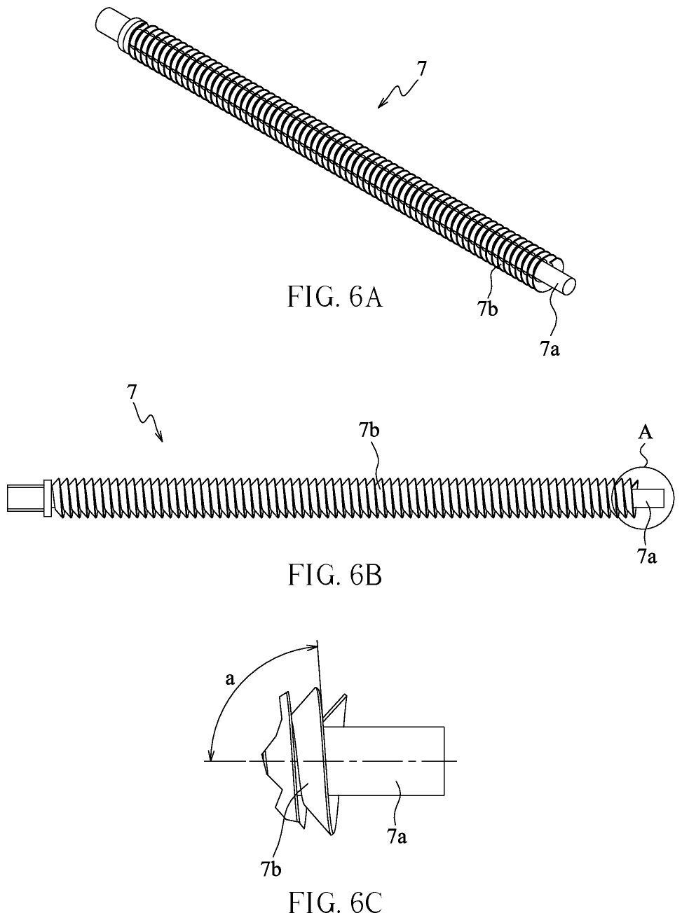

According to an embodiment of the present invention, FIG. 6A illustrates a perspective view of the heater 7; FIG. 6B is a side view of the heater 7 shown in FIG. 6A; and FIG. 6C is a partial enlarged view of a part A in FIG. 6B. As shown in FIGS. 6A-6B, the heater 7 may comprise a heating tube 7a and a fin 7b. The fin 7b may be formed helically around the heating tube 7a and may be attached to the heating tube 7a. The fin 7b can increase an area for heat transfer, thereby increasing the efficiency of heat transfer. As shown in FIG. 6C, the fin 7b is formed around the heating tube 7a with the axis of the heating tube 7a as a central axis. In one embodiment, an angle a formed by the hypotenuse of each helix of the fin 7b and the central axis may be from approximately 80° to approximately 90°, and the helical pitch of the fin 7b may be from approximately 3 mm to approximately 7 mm, in order to achieve a reduced pressure loss and an enhanced heat transfer efficiency. By spatially arranging an air intake module (the active air intake device) and the heating module, the uniformity of airflow heating can be improved.

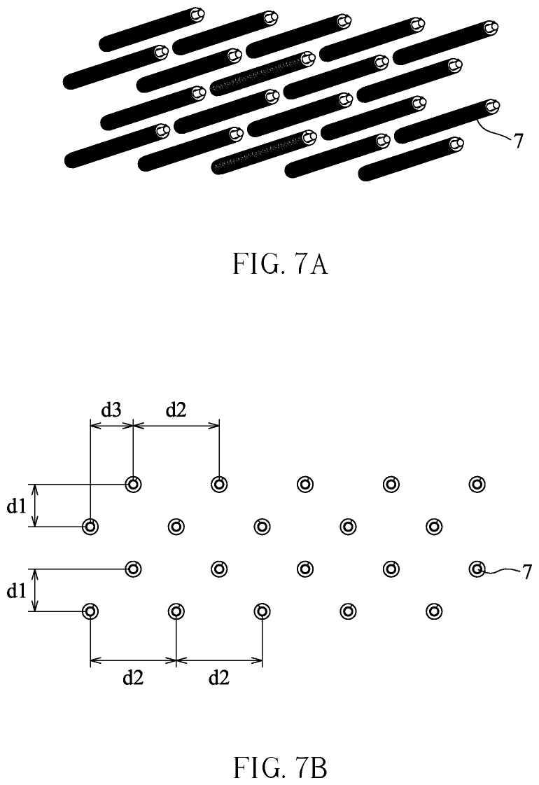

According to an embodiment of the present invention, FIG. 7A illustrates a perspective view of heaters 7 as shown in FIG. 6A arranged in multiple rows; and FIG. 7B is a front view of the multiple rows of heaters shown in FIG. 7A. As shown in FIGS. 7A and 7B, a plurality of heaters 7 are arranged into multiple rows of heaters. In the embodiments shown in FIGS. 5, 6A-6C, and 7A-7C, the heating tube 7a is a linear-shaped heating tube.

In an embodiment of the present invention, as shown in FIG. 7B, distances d1 between any two adjacent rows of heaters of the multiple rows of heaters may be substantially identical, and distances d2 between any two adjacent heaters in the same row of heaters may be substantially identical. In one example, each of the distances d1 may be from approximately 60 mm to approximately 70 mm, and each of the distances d2 may be from approximately 120 mm to approximately 150 mm. In another example, each of the distances d1 may be from approximately 55 mm to approximately 65 mm, and each of the distances d2 may be from approximately 40 mm to approximately 50 mm. In yet another example, each of the distances d1 may be from approximately 20 mm to approximately 30 mm, and each of the distances d2 may be from approximately 45 mm to approximately 55 mm. In addition, as shown in FIG. 7B, horizontal offset distances d3 may present between any two adjacent row of heaters of the multiple row of heaters. That is, any two adjacent rows of heaters of the multiple rows of heaters may be arranged in a staggered manner. In the embodiments of the present invention, each of the distance d3 is not particularly limited, as long as any two adjacent rows of heater are arranged in a staggered manner. While four rows of heaters 7 are shown in FIGS. 7A and 7B, those having ordinary skill in the art may increase or decrease the number of rows of the heaters 7 based on actual requirement.

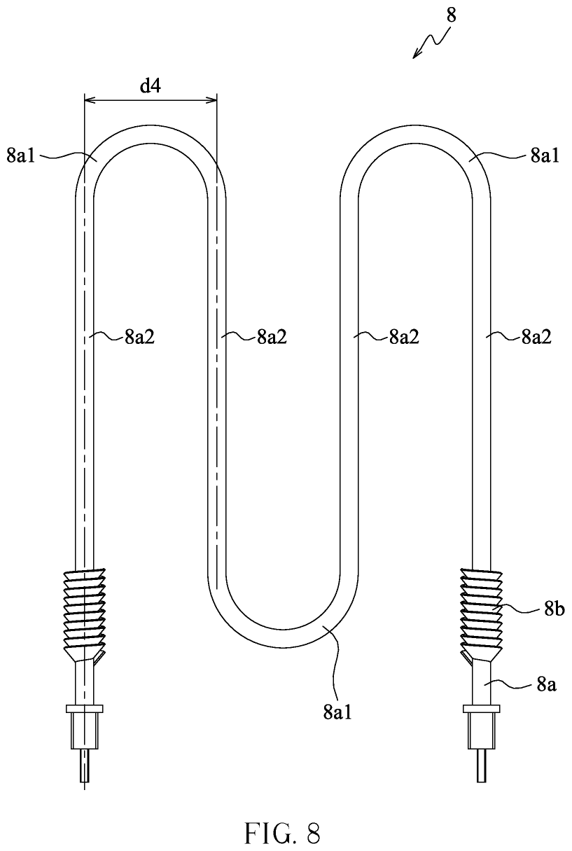

FIG. 8 illustrates a schematic view of a heater 8 according to another embodiment of the present invention. Similar to the heater 7, the heater 8 may also comprise a heating tube 8a and a fin 8b. The fin 8b can increase an area for heat transfer, thereby increasing the efficiency of heat transfer. In the embodiment shown in FIG. 8, the heating tube 8a is a curved heating tube, which may comprise alternating X U-shaped curved portions 8a1 and X+1 linear portions 8a2, where X is an integer greater than zero. As shown in FIG. 8, the first one and the last one of the linear portions are respectively connected to one of the U-shaped curved portions, and each of the remaining linear portions is connected to two of the U-shaped curved portions oriented in opposite directions. In an embodiment, distances d4 between any two adjacent ones of the linear portions may be substantially identical. In one example, each of the distances d4 may be from approximately 75 mm to approximately 85 mm. The fin 8b may be formed helically around the heating tube 8a and may be attached to the heating tube 8a. the fin 8b is formed around the heating tube 8a with the axis of the heating tube 8a as a central axis. Similar to the embodiment shown in FIG. 6C, an angle formed by the hypotenuse of each helix of the fin 8b and the central axis (such as the angle a in FIG. 6C) may be from approximately 80° to approximately 90°, and the helical pitch of the fin 8b may be from approximately 3 mm to approximately 7 mm, in order to achieve a reduced pressure loss and an enhanced heat transfer efficiency.

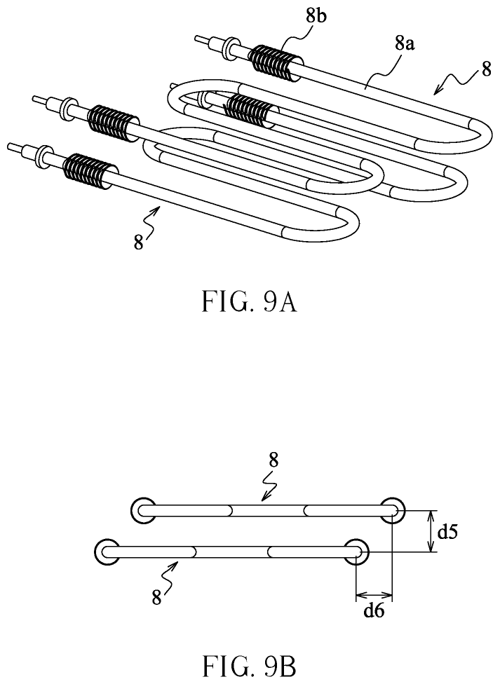

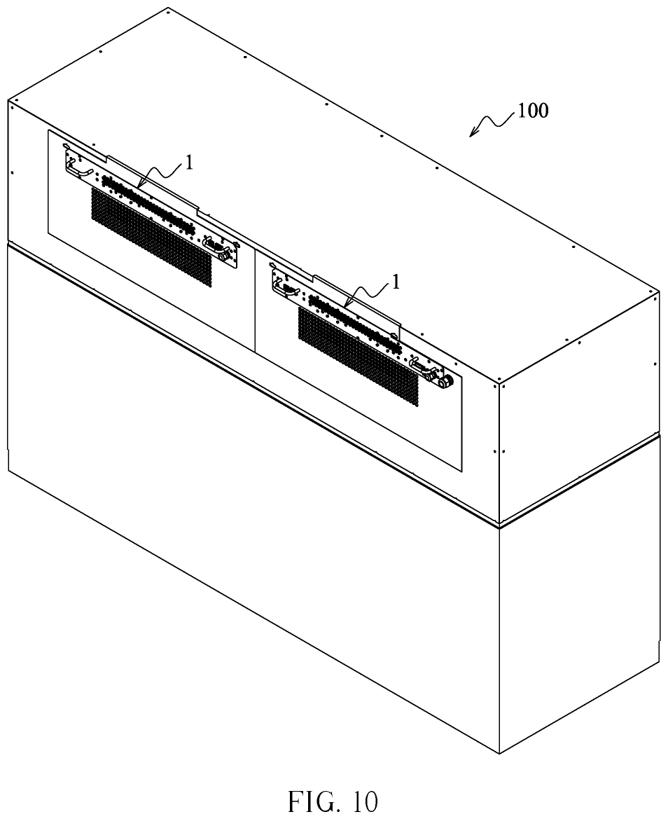

According to an embodiment of the present invention, FIG. 9A illustrates a perspective view of heaters 8 as shown in FIG. 8 arranged in multiple rows; and FIG. 9B is a front view of the multiple rows of heaters shown in FIG. 9A. As shown in FIGS. 9A and 9B, a plurality of heaters 8 are arranged into multiple rows of heaters. In an embodiments of the present invention, as shown in FIG. 9B, distances d5 between any two adjacent rows of heaters of the multiple rows of heaters may be substantially identical. In one example, each of the distances d5 may be from approximately 35 mm to approximately 45 mm. In addition, as shown in FIG. 9B, horizontal offset distances d6 may present between any two adjacent row of heaters of the multiple row of heaters. That is, any two adjacent rows of heaters of the multiple rows of heaters may be arranged in a staggered manner. In the embodiments of the present invention, the distance d6 is not particularly limited, as long as any two adjacent rows of heater are arranged in a staggered manner. While two rows of heaters 8 are shown in FIGS. 9A and 9B, those having ordinary skill in the art may increase or decrease the number of rows of the heaters 8 based on actual requirement. Further, for convenience of description, in FIGS. 8 and 9A, the fin 8b is shown to be provided around only a portion of the heating tube 8a. In fact, the fin 8b may be provided around the entire heating tube 8a, i.e., around all U-shaped curved portions 8a1 and linear portions 8a2. Moreover, a plurality of heaters 8 may be enclosed by the housing 9 as shown in FIG. 3, so as to improve the heating efficiency of the heaters 8. By spatially arranging an air intake module (the active air intake device) and the heating module, the uniformity of airflow heating can be improved.

In an embodiment of the present invention, the heating tube 7a and the heating tube 8a may be, for example, electric heating tubes, heating lamp tubes, or heating tubes utilizing other heating mechanisms, but it is not limited thereto.

FIG. 10 illustrates a perspective view showing an EFEM 100 equipped with airflow heating modules 1, according to an embodiment of the present invention. While two airflow heating modules 1 are shown in FIG. 10, those having ordinary skill in the art may increase or decrease the number of the airflow heating module 1 based on actual requirement.

Although the present invention has been described in detail with reference to the preferred embodiments and drawings for the purpose of illustration, it is to be understood that those embodiments are illustrative rather than limiting. Further, those with ordinary skill in the art may implement various modifications, changes, and equivalents without departing from the spirit and scope of the present invention. Therefore, it is to be understood that the scope of the present invention is defined by the following claims, and these modifications, changes, and equivalents should also be included in the scope of the present invention.

What is claimed is:

1. An airflow heating module for an equipment front-end module, comprising:
a first perforated plate comprising a first plurality of holes used as airflow inlets;
a second perforated plate comprising a second plurality of holes used as airflow outlets;
a plurality of heaters provided between the first perforated plate and the second perforated plate; and
an active air intake device provided on the first perforated plate, and configured to accelerate airflow flowing through the first plurality of holes and flowing past the plurality of heaters, such that the airflow carries heat generated by the plurality of heaters and passes through the second plurality of holes,
wherein each of the plurality of heaters includes a heating tube and a fin, and
wherein the fin is formed helically around the heating tube and is attached to the heating tube.

2. The airflow heating module of claim 1, wherein the plurality of heaters are arranged into multiple rows of heaters, wherein distances between any two adjacent rows of heaters of the multiple rows of heaters are substantially identical, and wherein any two adjacent rows of heaters of the multiple rows of heaters are arranged in a staggered manner.

3. The airflow heating module of claim 2, wherein the fin is formed around the heating tube with the axis of the heating tube as a central axis, wherein an angle formed by a hypotenuse of each helix of the fin and the central axis is from 80° to 90°, and wherein a helical pitch of the fin is from 3 mm to 7 mm.

4. The airflow heating module of claim 2, wherein the heating tube is a linear-shaped heating tube, and wherein distances between any two adjacent heaters in the same row of heaters are substantially identical.

5. The airflow heating module of claim 2,
wherein the heating tube is a curved heating tube comprising alternating X U-shaped curved portions and X+1 linear portions, wherein X is an integer greater than zero,
wherein the first one and the last one of the linear portions are respectively connected to one of the U-shaped curved portions, and each of the remaining linear portions is connected to two of the U-shaped curved portions oriented in opposite directions, and
wherein distances between any two adjacent ones of the linear portions are substantially identical.

6. The airflow heating module of claim 1, wherein the heating tube is an electric heating tube.

7. The airflow heating module of claim 1, wherein the heating tube is a heating lamp tube.

8. The airflow heating module of claim 4, wherein each of the distances between any two adjacent rows of heaters of the multiple rows of heaters is from 60 mm to 70 mm, and wherein each of the distances between any two adjacent heaters in the same row of heaters is from 120 mm to 150 mm.

9. The airflow heating module of claim 4, wherein each of the distances between any two adjacent rows of heaters of the multiple rows of heaters is from 55 mm to 65 mm, and wherein each of the distances between any two adjacent heaters in the same row of heaters is from 40 mm to 50 mm.

10. The airflow heating module of claim 4, wherein each of the distances between any two adjacent rows of heaters of the multiple rows of heaters is from 20 mm to 30 mm, and wherein each of the distances between any two adjacent heaters in the same row of heaters is from 45 mm to 55 mm.

11. The airflow heating module of claim 5, wherein each of the distances between any two adjacent rows of heaters of the multiple rows of heaters is from 35 mm to 45 mm, and wherein each of the distances between any two adjacent ones of the linear portions is from 75 mm to 85 mm.

12. The airflow heating module of claim 1, wherein the active air intake device is an air intake fan.

13. The airflow heating module of claim 1, further comprising a housing configured to enclose the plurality of heaters.
